(19) United States
(12) Patent Application Publication
(10) Pub. No.: US 2006/0091392 A1
(43) Pub. Date: May 4, 2006

(54) Electrically conductive structure, method of forming the same, an array substrate using the electrically conductive structure and a liquid crystal display panel including the electrically conductive structure

(75) Inventors: In Lee, Yongin-si (KR); Jin-Oh Kwag, Suwon-si (JP); Sung-Ho Lee, Hwaseong-si (KR); Young-Bin Kim, Geumsan-gun (KR)

Correspondence Address: David W. Heid;MacPHERSON KWOK CHEN & HEID LLP, Suite 226, 1762 Technology Drive, San Jose, CA, 95110, US

(73) Assignee: SAMSUNG ELECTRONICS CO., LTD., Suwon-si (KR)

(21) Appl. No.: 11/263,606

(22) Filed: Oct. 28, 2005

(30) Foreign Application Priority Data
Oct. 28, 2004 (KR) 200486723

(51) Int. Cl. H01L 29/04

(52) U.S. Cl. 257/60

(57) ABSTRACT

An electrically conductive structure includes a layer of metal and a barrier layer. The layer of metal is disposed on an insulating body. The barrier layer covers an upper face and a side face of the metal layer and the barrier layer comprises a material having a melting point higher than a glass transition temperature of the insulating body.

### CROSS-REFERENCE TO RELATED APPLICATIONS

This application relies for priority upon Korean Patent Application No. 2004-86723 filed on Oct. 28, 2004, the contents of which are herein incorporated by reference in its entirety.

### BACKGROUND OF THE INVENTION

1. Field of the Invention

The present invention relates to a metal wiring, a method of forming the metal wiring, an array substrate having the metal wiring and a liquid crystal display panel having the metal wiring. More particularly, the present invention relates to a metal wiring capable of reducing defects, a method of forming the metal wiring, an array substrate having the metal wiring and a liquid crystal display panel having the metal wiring.

2. Description of the Related Art

Generally, a liquid crystal display (LCD) device includes an array substrate on which a thin film transistor (TFT) is formed, a counter substrate facing the array substrate and liquid crystal layer disposed between the array substrate and the counter substrate. When an electric field is applied to the liquid crystal layer having an anisotropic electric permittivity, an arrangement of liquid crystal molecules of the liquid crystal layer are altered to change optical transmissivity. Thus, an amount of light passing through the array substrate and the counter substrate is controlled to display an image.

The array substrate usually includes a TFT disposed on a first transparent substrate, a gate line electrically connected to a gate electrode of the TFT, a data line electrically connected to a source electrode of the TFT and a pixel electrode electrically connected to a drain electrode of the TFT.

Generally, the transparent substrate of the array substrate includes glass. The gate electrode and the gate line include metal. The gate electrode and the gate line are disposed on the transparent substrate.

When the size the LCD device increases, the length of the gate lines also which increases the electrical resistance of the gate line. Thus, the magnitude of the voltage applied to a TFT located near an edge portion of the LCD device is different than the magnitude of a voltage applied to a TFT which disposed on a central portion of the LCD device. Accordingly the display quality of the LCD device deteriorates. As a result, metal having a low specific resistance such as copper (Cu) has been tested for use as gate lines and gate electrodes.

However, copper has a low adhesive force to glass, so that the gate electrode or the gate line can become easily separated from the array substrate. Thus, the TFT operates abnormally.

In addition, copper atoms diffuse into a gate insulation layer which includes silicon (Si). Accordingly the electrical resistance of the gate electrode increases, and this causes a signal transmitted to the gate electrode to be delayed.

### SUMMARY OF THE INVENTION

The present invention obviates the above problems and thus the present invention provides a metal wiring structure capable of preventing diffusion of a copper atom.

The present invention also provides a method of forming the above-mentioned metal wiring.

The present invention also provides an array substrate having the above-mentioned metal wiring.

The present invention also provides a method of manufacturing the above-mentioned array substrate.

The present invention also provides an LCD panel having the above-mentioned metal wiring.

In one aspect of the present invention, a metal wiring includes a metal layer and a barrier layer. The metal layer is disposed on an insulation substrate. The barrier layer covers an upper face and a side face of the metal layer, includes a material having a melting point higher than a glass transition temperature of the insulation substrate and prevents the diffusion of atoms in the metal layer.

In another aspect of the present invention, a method of forming a metal wiring includes forming a metal layer on an insulation substrate and coating a material having a melting point higher than a glass transition temperature of the insulation substrate on an upper face and a side face of the metal layer to form a barrier layer preventing the diffusion of atoms in the metal layer. The metal layer may be formed by an electroless plating method.

In still another aspect of the present invention, an array substrate includes an insulation substrate, a switching element and a pixel electrode. The switching element includes a gate electrode electrically connected to gate lines and having a metal, a first current electrode electrically connected to data lines, a gate insulation layer insulating the gate electrode and the first current electrode from each other and a first barrier layer between the gate electrode and the gate insulation layer. The first barrier covers an upper face and a side face of the gate electrode, includes a material having a melting point higher than a glass transition temperature of the insulation substrate and prevents the diffusion of the metal. The pixel electrode is electrically connected to a second current electrode of the switching element.

In still another aspect of the present invention, a method of manufacturing an array substrate includes forming a gate electrode including a metal on an insulation substrate, depositing a material having a melting point higher than a glass transition temperature of the insulation substrate on an upper face and a side face of the gate electrode to form a barrier layer preventing the diffusion of atoms in the metal and successively forming a gate insulation layer, a first current electrode and a second current electrode on the insulation substrate including the barrier layer.

In still another aspect of the present invention, an LCD panel includes a first glass substrate, a second glass substrate and a liquid crystal layer. The first glass substrate includes a common electrode. The second glass substrate facing the first glass substrate includes a switching element and a pixel electrode. The switching element has a gate electrode including a metal, a gate insulation layer, a first current electrode, a second current electrode and a barrier layer between the gate electrode and the gate insulation layer. The switching element includes a material having a melting point higher than a glass transition temperature of the first glass substrate, prevents the metal diffusion and applies an image signal. The pixel electrode is electrically connected to the switching element. The liquid crystal layer is interposed between the first and second glass substrates.

According to the above, an adhesive force between the insulation substrate and a conductive line increases and an electrical resistance of the conductive line decreases, thereby improving display quality of the display device and preventing the diffusion of the metallic material of the conductive line, so that defects of the display device may be restrained.

### BRIEF DESCRIPTION OF THE DRAWINGS

The above and other features and advantages of the present invention will become more apparent from the following detailed description of exemplary embodiments with reference to the accompanying drawings, in which:

FIG. 1 is a layout illustrating a portion of an array substrate according to an exemplary embodiment of the present invention;

FIG. 2 is a cross-sectional view taken along a line 2-2 in FIG. 1;

FIGS. 3A through 3F are cross-sectional views illustrating a method of manufacturing an LCD device according to an exemplary embodiment of the present invention;

FIG. 4 is a flow chart illustrating a method of forming a metal wiring according to an exemplary embodiment of the present invention;

FIG. 5 is a graph illustrating surface roughness resulting from etching conducted with the indicated etching solutions;

FIG. 6 is a graph illustrating adhesive force results from scratch tests for a plurality etching solutions;

FIG. 7 is a graph illustrating the results of pull tests for a plurality of etching solutions;

FIG. 8 is a graph illustrating the results of adhesion tests achieved for a sensitizing-activating process and a catalyzing-accelerating process;

FIG. 9 is a graph showing three curves which plot plating speed as a function of temperature for a complexing agent of EDTA at three different pH values;

FIG. 10 is a graph showing three curves which plot plating speed as a function of temperature for a complexing agent of Rochelle salt at three different pH values; and

FIGS. 11 and 12 are graphs illustrating an X-ray diffraction pattern of a transparent substrate including a copper plating.

### DESCRIPTION OF THE EMBODIMENTS

The present invention is described fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, region or substrate is referred to as being “on” or “onto” another element, it may be directly on the other element or intervening elements may also be present.

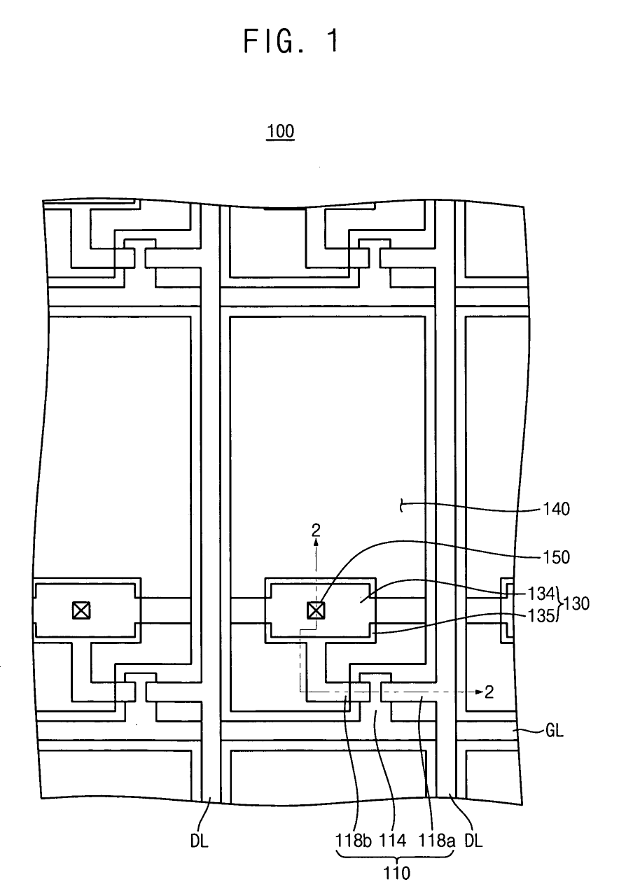

FIG. 1 is a layout illustrating a portion of an array substrate according to an exemplary embodiment.

Referring to FIG. 1, an array substrate 100 includes a plurality of gate lines GL formed in a first direction, a plurality of data lines DL formed in a second direction intersecting the first direction and a plurality of pixel regions defined by the gate lines GL and the data lines DL.

A switching element 110, a storage capacitor 130 and a pixel electrode 140 are formed on each of the pixel regions. The storage capacitor 130 is electrically connected to the switching element 110. The pixel electrode 140 corresponds to a first electrode of a liquid crystal capacitor.

The switching element 110 includes a gate electrode 114 electrically connected to one of the gate lines GL, a source electrode 118a electrically connected to one of the data lines DL and a drain electrode 118b electrically connected to the pixel electrode 140 via a contact hole 150. A semiconductor layer (not shown) is formed between the gate electrode 114 and the source electrode 118a, and between the gate electrode 114 and the drain electrode 118b.

The gate electrode 114 which is electrically connected to the gate line GL includes a first metal layer (not shown) and a first barrier layer (not shown).

The first metal layer includes, for example, copper. Copper has a relatively low specific resistance of about 1.67 μΩ·cm. Copper satisfies a pixel electrode condition that the first metal layer have a resistance that is lower than about 3.0 μΩ·cm. Copper, however, easily reacts with silicon.

The first barrier layer covers a remaining portion of the first metal layer except for a portion making contact with a base substrate of the array substrate 100. That is, the first barrier layer covers all of an upper face and four side faces of the first metal layer. The first barrier layer includes a material that has good characteristics at a high temperature in order to undergo following processes. The first barrier layer includes, for example, tin oxide (SnO₂) and zinc oxide (ZnO₂). Tin oxide has a melting point that is higher than a glass transition temperature of about 750° C.

When the first metal layer includes copper, the first barrier layer prevents copper atoms from diffusing into, for example, a gate insulation layer including silicon or a passivation layer through a high temperature process that will be described later.

The first barrier layer is formed between the first metal layer and the gate insulation layer, and/or between the first metal layer and the passivation layer to prevent the diffusion of copper atoms. Thus, the first barrier layer restricts an increase in resistance of the gate electrode 114 including the first metal layer, the increase in resistance being caused by diffusion of copper atoms. As a result, a signal delay of the gate electrode 114 may be prevented.

The storage capacitor 130 includes a first electrode 134 which is made of a material which is substantially the same material as the gate lines GL, and a second electrode 135 having substantially same material as the drain electrode 118b. The storage capacitor 130 maintains a voltage of the liquid crystal capacitor for one frame even when the switching element 110 is turned off.

Although only the gate electrode 114 includes the first metal layer having copper and the first barrier layer as described above, alternatively, the above-described structure may be applied to the gate lines GL and the data lines DL.

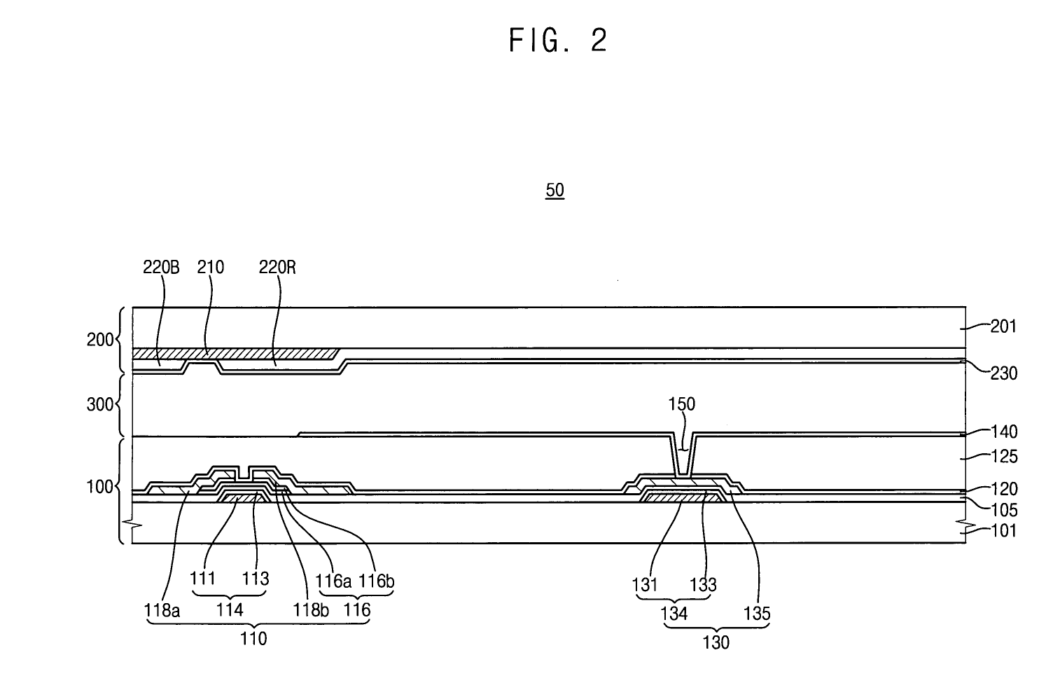

FIG. 2 is a cross-sectional view taken along a line 2-2 of FIG. 1.

Referring to FIG. 2, a liquid crystal display (LCD) panel 50 includes an array substrate 100, a color filter substrate 200, and a liquid crystal layer 300 interposed between the array substrate 100 and the color filter substrate 200.

The array substrate 100 includes a first transparent substrate 101, a switching element 110 and a pixel electrode 140.

The switching element 110 is electrically connected to the gate lines. The switching element 110 applies a voltage to the pixel electrode 140 via the source and drain electrodes 118a and 118b. The switching element 110 includes the gate electrode 114, a gate insulation layer 105, a semiconductor layer 116 and the source and drain electrodes 118a and 118b.

The gate electrode 114 includes a first metal layer 111 and a first barrier layer 113, and is electrically connected to the gate lines GL.

When the first metal layer 111 includes copper, the first metal layer 111 may have a poor adhesivity with the first transparent substrate 101. Thus, the first metal layer 111 may include a first seed layer (not shown). The first seed layer, for example, includes at least one of palladium (Pd), gold (Au), silver (Ag), tin (Sn), nickel (Ni), iron (Fe), and platinum (Pt). The first seed layer provides a seed for depositing the first metal layer 111 on the first transparent substrate 101 when the first metal layer 111 is formed through an electroless plating method.

The first barrier layer 113 is disposed to cover the first metal layer 111 except for a portion thereof which makes contact with the first transparent substrate 101. In other words, the first barrier layer 113 covers all of an upper face and side faces of the first metal layer 111.

When the first metal layer 111 includes copper, unless a barrier layer is provided between the first metal layer 111 and the gate insulation layer 105, copper atoms from the first metal layer 111 will diffuse into the silicon containing gate insulation layer 105 that is adjacent to the first metal layer 111, so that the copper atoms may easily react with silicon. Accordingly, first barrier layer 113 is disposed between the first metal layer 111 and the gate insulation layer 105, so that the copper atoms are prevented from diffusing into the gate insulation layer 105 and reacting with silicon in the gate insulation layer 105. Thus, the first barrier layer 113 reduces an increase in electrical resistance of the gate electrode 114. As a result, a signal delay to the gate electrode 114 due to increased resistance of the gate line is prevented.

The first barrier layer 113 is constructed from a material which is stable at high temperatures, such as tin oxide and zinc oxide. Thus, the first barrier layer 113 is stable under succeeding high temperature processes such as an ion implantation process used for doping N+ type impurities in an amorphous silicon layer 116b. The first barrier layer 113 may include a conductive oxide material.

The first electrode 134 of the storage capacitor 130 and the gate lines GL are typically constructed from the same material as that of the gate electrode 114. Thus, the first electrode 134 includes a second metal layer 131 and a second barrier layer 133 covering an upper face and side faces of the second metal layer 131. The gate lines GL include a third metal layer (not shown) and a third barrier layer (not shown) covering an upper face and side faces of the third metal layer.

Referring to FIG. 2, the gate insulation layer 105 is formed on the first and second barrier layers 113 and 133 respectively, and on an exposed portion of the first transparent substrate 101. The gate insulation layer 105 electrically insulates the gate electrode 114 from the source electrode 118a and the drain electrode 118b. The gate insulation layer 105, for example, typically includes silicon nitride (SiNx), or silicon oxide (SiOx).

The semiconductor layer 116 is disposed on the gate insulation layer 105. The semiconductor layer 116 includes an active layer 116a and an ohmic contact layer 116b. The semiconductor layer 116 is positioned above gate electrode 114.

The source electrode 118a and the drain electrode 118b are electrically connected to the data lines DL and the second electrode 135 of the storage capacitor 130, respectively. The source electrode 118a may include a conductive metallic material. The source electrode 118a, the drain electrode 118b, the data lines DL and the second electrode 135 of the storage capacitor 130 may include a fourth metal layer (not shown) and a fourth barrier layer (not shown).

When the fourth metal layer includes copper, the fourth metal layer may poorly adhere to first transparent substrate 101. Also, the fourth metal layer may include a second seed layer (not shown). The second seed layer provides a seed for depositing the fourth metal layer on the first transparent substrate 101. The fourth metal layer including copper may be formed on the first transparent substrate 101 through an electroless plating method.

The fourth barrier layer is disposed to cover a remaining portion of the fourth metal layer except for a portion making contact with the first transparent substrate 101. In other words, the fourth barrier layer covers all of an upper face and side faces of the fourth metal layer.

The fourth barrier layer is formed between the fourth metal layer and a passivation layer 120 disposed on the source electrode 118a and the drain electrode 118b to prevent copper atoms of the fourth metal layer from diffusing into the passivation layer 120. Thus, the fourth barrier layer reduces an increase in electrical resistance of the source electrode 118a and the drain electrode 118b which would otherwise result from the diffusion of the copper atoms out of the source and drain electrodes. As a result, a signal delay due to increased resistance of the source electrode 118a and the drain electrode 118b is prevented. The fourth barrier layer may include a conductive oxide material.

The passivation layer 120 is disposed on the source and drain metal layers to protect the switching element 110. An organic layer 125 is disposed on the passivation layer 120. The use of organic layer 125 is optional.

The organic layer 125 is disposed over the first transparent substrate 101 on which the switching element 110 and the passivation layer 120 are formed. The organic layer 125 controls a thickness of the liquid crystal layer, and planarizes the first transparent substrate 101. The organic layer 125 includes a contact hole 150 partially exposing the drain electrode 118b. The passivation layer 120 and the organic layer 125 are etched to form the contact hole 150. The contact hole 150 exposes a portion of the drain electrode 118b.

The pixel electrode 140 is disposed on the organic layer 125, and may include a transparent conductive material. The pixel electrode 140 is electrically connected to the drain electrode 118b via the contact hole 150. The pixel electrode 140, for example, includes a transparent conductive material such as indium tin oxide (ITO), indium zinc oxide (IZO), and zinc oxide (ZnO). Alternatively, the pixel electrode 140 may include a reflective electrode having a high optical reflectivity. Alternatively, the pixel electrode 140 may include a transparent electrode having a transparent conductive material and a reflective electrode disposed on the transparent electrode and having a high optical reflectivity.

A color filter substrate 200 includes a second transparent substrate 201, a light-intercepting layer 210, pixel patterns 220R and 220B and a transparent electrode layer 230.

The light-intercepting layer 210 is disposed on the second transparent substrate 201 to intercept light. The light-intercepting layer 210 defines a pixel region and a light-intercepting region on the second transparent substrate 201.

The pixel patterns 220R and 220B may be disposed on the pixel region defined by the light-intercepting layer 210. The pixel patterns 220R and 220B include a color filter transmitting light having a wavelength corresponding to an intrinsic color in response to incident light. The pixel patterns may include red, green and blue color filters.

The common electrode 230 corresponds to the pixel electrode 140 of the array substrate 100, and a common voltage is applied to the common electrode 230. Thus, a liquid crystal capacitor is defined by the pixel electrode 140 serving as a first electrode for the liquid crystal capacitor and the common electrode 230 serving as a second electrode for the liquid crystal capacitor. A planarization layer may be formed on the light-intercepting layer 210 and the pixel patterns 220R and 220B to planarize and protect the pixel patterns 220R and 220B.

Liquid crystal molecules of the liquid crystal layer 300 are rearranged in accordance with a voltage applied to the pixel electrode 140 of the array substrate 100 and the common electrode 230 of the color filter substrate 200 to allow the LCD panel 50 to display an image.

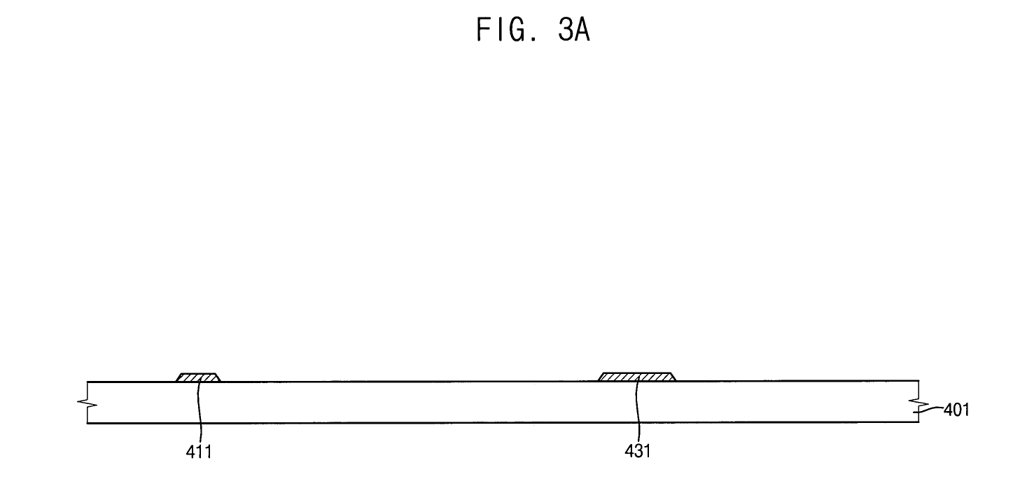

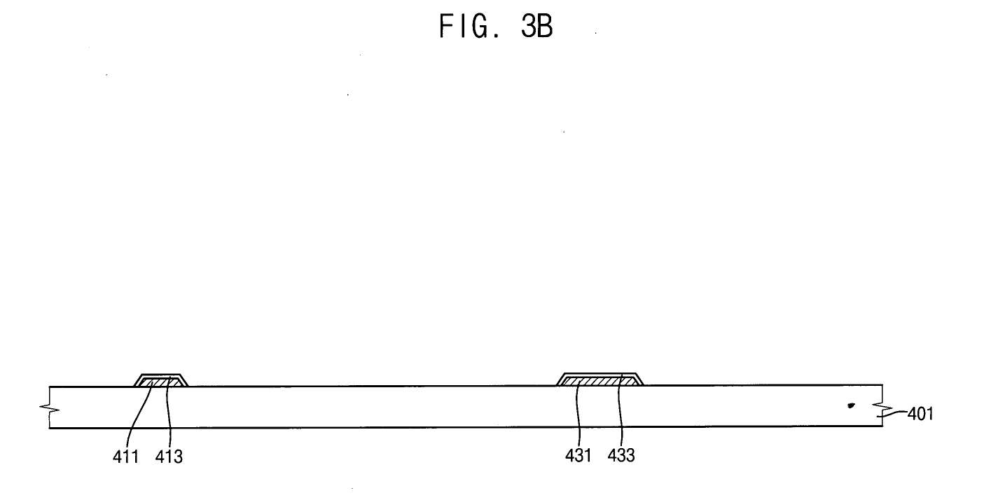

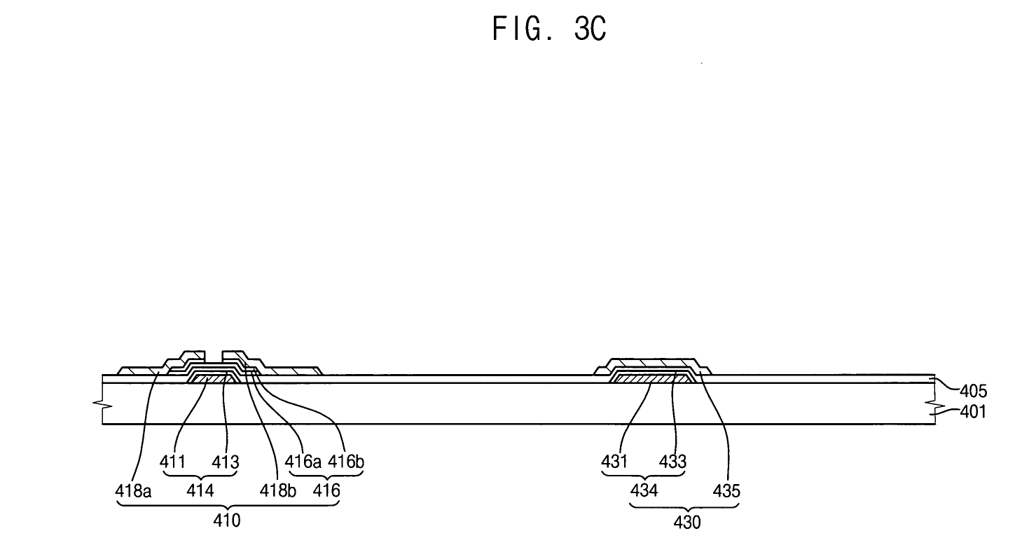

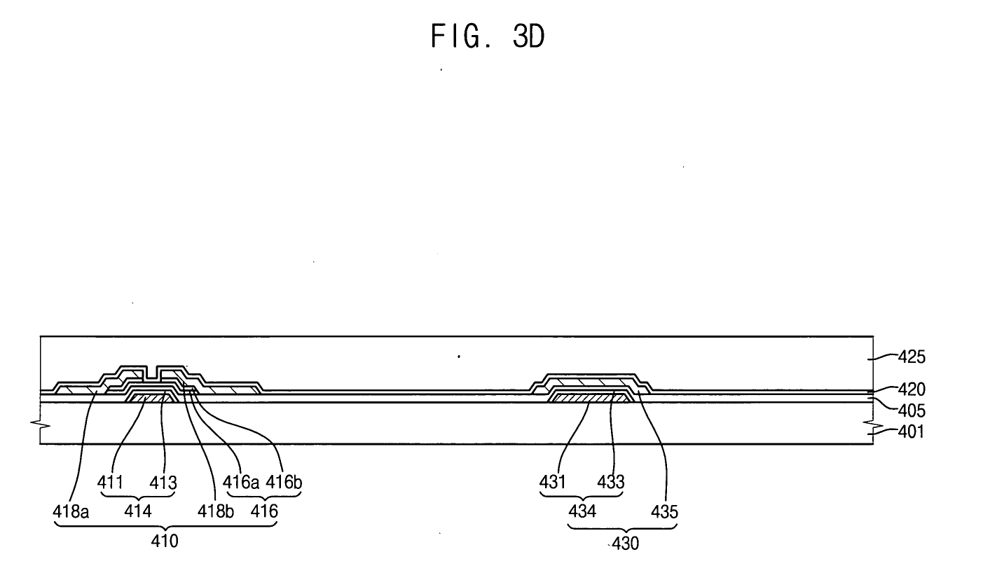

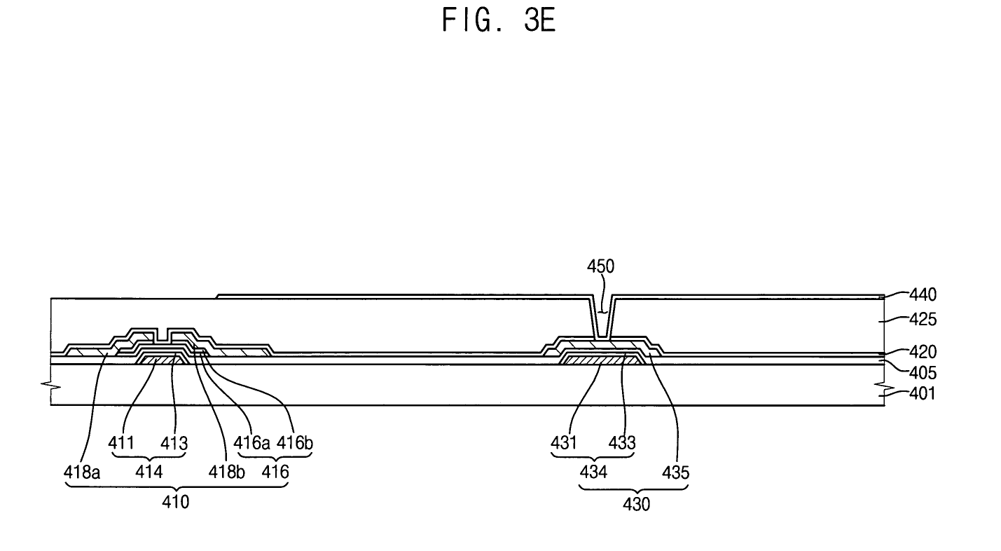

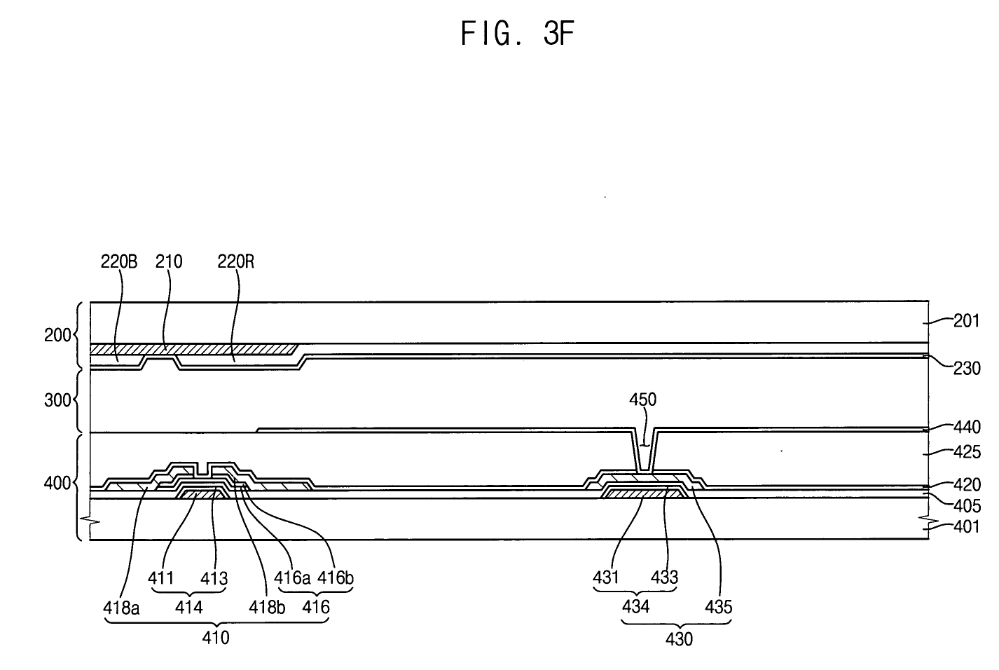

FIGS. 3A to 3F are cross-sectional views illustrating a method of manufacturing a liquid crystal display device according to an exemplary embodiment of the present invention.

Referring to FIG. 3A, first and second metal layers 411 and 431 are formed on a transparent substrate 401, for example through an electroless plating method. The first and second metal layers 411 and 431 include copper.

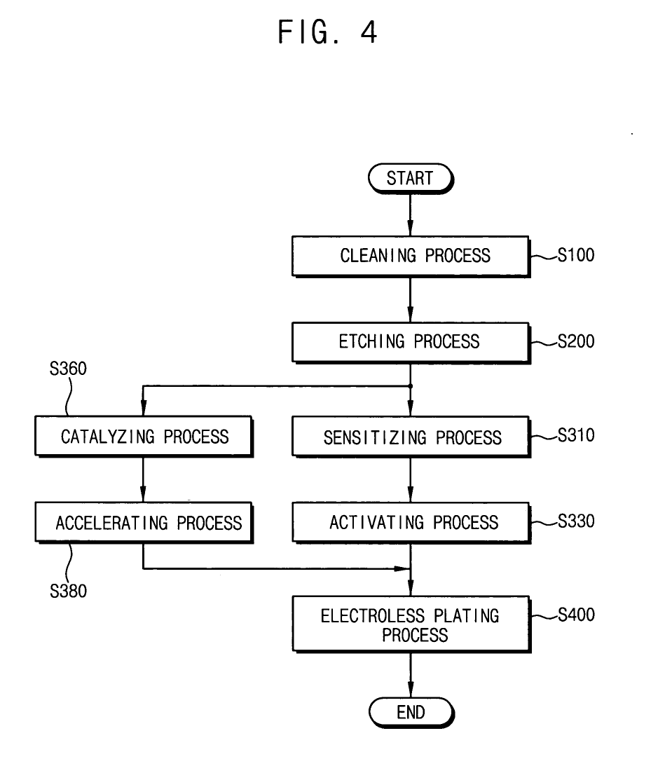

FIG. 4 is a flow chart illustrating a method of forming a metal wiring according to an exemplary embodiment.

Referring to FIGS. 3A and 4, the electroless plating method includes a pre-treatment process and a metal layer growing process. The pre-treatment process includes a cleaning process S100, an etching process S200, a sensitizing process S310 and an activating process S330.

In the cleaning process S100, the transparent substrate 401 is dipped in deionized water (DIW) to remove impurities such as a polymer attached to the transparent substrate 401.

Then, in the etching process S200, the transparent substrate 401 is dipped in an etching solution having an etchant additive. Suitable etching solutions include hydrogen fluoride (HF), ammonium fluoride (NH₄F), and sodium hydroxide (NaOH), and potassium hydroxide (KOH). The etching solution may also include sodium chloride (NaCl). In the etching process S200, a surface particle of the transparent substrate 401 to which copper is adsorbed has a reduced size, so that an adsorption force of the copper to the transparent substrate 401 increases.

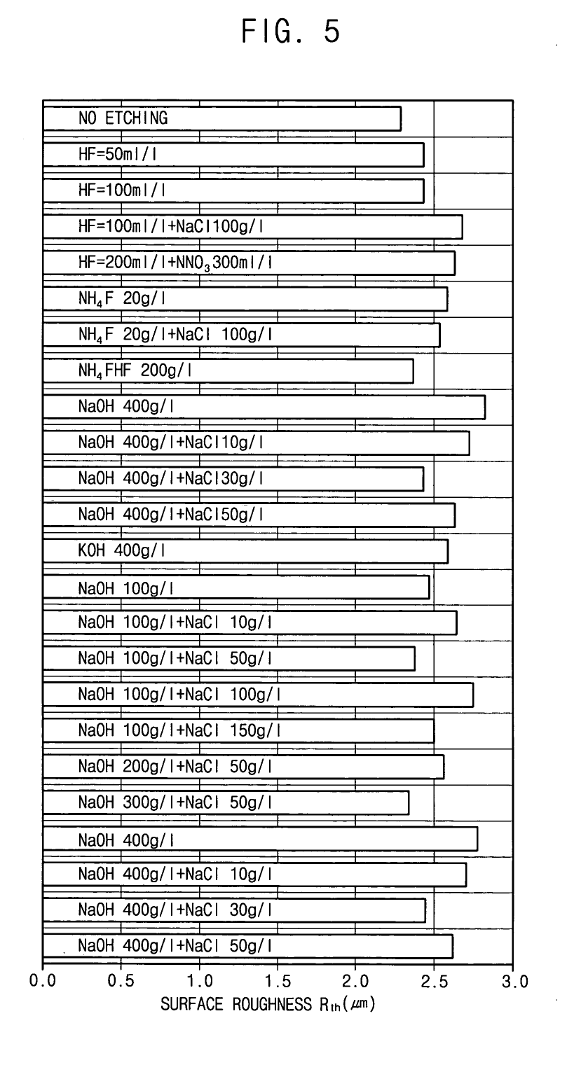

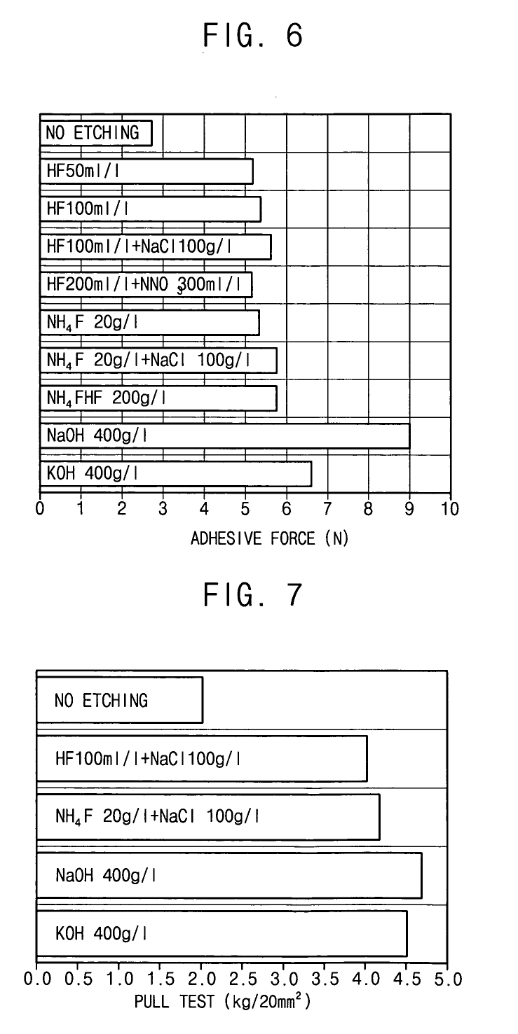

FIG. 5 is a graph illustrating the surface roughness resulting from the kind of an etching solution and a concentration of an additive. FIG. 6 is a graph illustrating a result of a scratch test in accordance with a kind of an etching solution and a concentration of an additive. FIG. 7 is a graph illustrating a result of a pull test in accordance with a kind of an etching solution and a concentration of an additive.

A tape-casted aluminum oxide (Al₂O₃) was employed as a workpiece, which had a size of about 5 cm×5 cm×0.5 cm and a purity of about 96%. The etching solution was one of hydrogen fluoride (HF), ammonium fluoride (NH₄F), sodium hydroxide (NaOH) and potassium hydroxide (KOH). The etching process was performed for about fifteen minutes. The additive was sodium chloride (NaCl). The etching process was performed under the above conditions to form an electroless copper plating film having a mean thickness of about 10 μm, and a surface roughness test, a scratch test and a pull test were performed.

Referring to FIGS. 5, 6 and 7, the workpiece that is etched by an etching solution including sodium hydroxide (NaOH) of about 400 g/L and the workpiece that is etched by an etching solution including sodium hydroxide (NaOH) of about 100 g/L and sodium chloride (NaCl) of about 100 g/L had the roughest surface, so that the workpiece had the greatest adhesive force of about 18N with respect to the copper film having a thickness of about 10 μm.

Even though a small amount of sodium chloride (NaCl) is added to the sodium hydroxide (NaOH) of about 400 g/L, an adhesive force is rapidly decreased. This is because of two much negative ions of hydroxide ions OH⁻ and chloride ions (Cl⁻) of sodium chloride (NaCl), which were added to the etching solution in order to effectively etch the workpiece.

Then, a sensitizing process is performed. That is, the transparent substrate is dipped in a metal chloride acid solution, so that tin ions (Sn²⁺) adhere to a surface of the transparent substrate. For example, a workpiece is dipped in a solution including tin (II) chloride (SnCl₂) of about 10 g/L and hydrochloric acid of about 30 ml/L at a normal temperature for about one to about two minutes, thereby adsorbing the tin ions to a surface of the workpiece. Then, the workpiece is dipped in water and the water containing the workpiece is stirred in order to remove impurities. The workpiece is taken out of the water. For example, in order to change a surface of the workpiece to be hydrophillic, ultrasonic waves may be applied to the surface of the workpiece for about ten seconds. Then, the sensitizing process may be ironed out.

Due to the sensitizing process, a seed may be easily deposited on the workpiece.

After the sensitizing process is performed, an activating process is performed. In detail, the workpiece is dipped in a metal chloride solution to grow a seed in a predetermined region of the workpiece. For example, the workpiece is dipped in a solution including palladium chloride (PdCl₂) of about 0.3 g/L and hydrochloric acid of about 30 ml/L for about one to about two minutes. Then, a chemical reaction corresponding to the following chemical equation is performed.

Chemical Equation
Sn²⁺+Pd²⁺→Pd+Sn⁴⁺

Then, tin ions (Sn⁴⁺) are removed through a washing process, so that palladium (Pd) is adhered to the surface of the workpiece to which the tin ions are adhered. Palladium corresponds to a metal having an atomic number of forty-six, an atomic weight of about 106.4, a specific gravity of about 12.02 and a melting point of about 1552° C. Palladium is chemically stable, and is the most inexpensive in group ten of periodic table, which includes nickel (Ni), palladium (Pd) platinum (Pt) and darmstadtium (Ds), so that palladium is widely used in an electroless plating process.

The sensitizing process and the activating process have the disadvantage that in a succeeding plating process, tin (IV) hydroxide (Sn(OH)₄) may remain on the surface of the workpiece. Thus, an additional process for treating the surface of the workpiece may be performed. Hence, a catalyzing-accelerating processes S360 and S380 respectively may be performed instead of the sensitizing process S310 and the activating process S330.

The catalyzing-accelerating process may be performed by dipping the workpiece in polymer of PdCl₂—SnCl₂—HCl mixture serving as a catalyst solution. The polymer, for example, includes palladium chloride (PdCl₂) of about 0.5 g/L, tin (II) chloride (SnCl₂) of about 25 g/L and hydrochloric acid of about 30 ml/L. Then, adsorption salt is washed to be hydrolyzed, so that divalent tin ions, tetravalent tin 20 ions and palladium salts coexist. In an accelerator including hydrochloric acid of about 100 ml/L, the precipitated stannous and stannic salts are removed, so that palladium ions (Pd²⁺) already separated from a complex ion react with tin ions (Sn²⁺) to form palladium (Pd) metal and tin ions (Sn⁴⁺). Then, in a washing process, divalent and tetravalent tin salts are removed.

A large amount of palladium is consumed in the catalyzing-accelerating process, thus resulting in increased manufacturing costs.

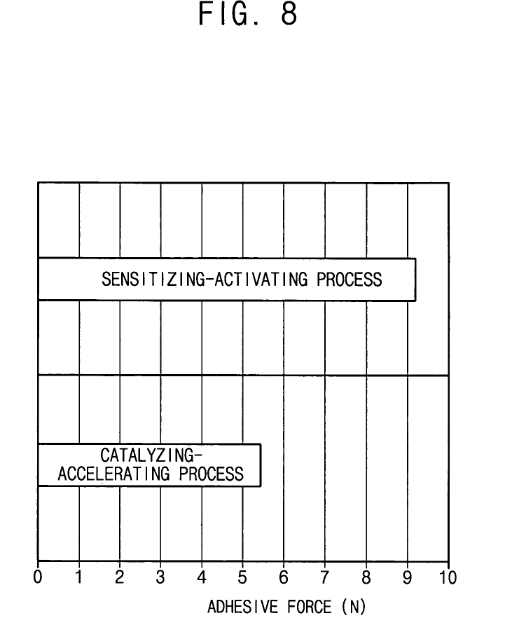

FIG. 8 is a graph illustrating the results of an adhesion test in accordance with a sensitizing-activating process and a catalyzing-accelerating process.

Referring to FIG. 8, experimental conditions of the sensitizing-activating process are substantially same as the catalyzing-accelerating process. As will be appreciated by reference to FIG. 8, a copper plating formed through the sensitizing-activating process had a stronger adhesive force to the workpiece than that of a copper plating formed through the catalyzing-accelerating process. Thus, it may be inferred that a copper plating film formed through the sensitizing-activating process has a relatively stronger adhesion to the workpiece.

In order to examine a selectivity of the copper plating, adhesivities of the copper plating in accordance with various pre-treatment processes and complexing agents were tested. Each of the activating process, the sensitizing-activating process, and the catalyzing-accelerating process was employed as the pre-treatment process, and each of ethylene di-amine tetra-acetic acid (EDTA) and Rochelle salt was employed as the complexing agent. The experimental results are as follows.

Table 1 below shows selectivities of the copper plating in accordance with the pre-treatment process.

TABLE 1

| Compexing agent | Pre-treatment process | Selectivity |
|---|---|---|
| EDTA | activating process | bad |
| | sensitizing-activating process | good |
| | catalyzing-accelerating process | good |
| Rochelle salt | activating process | bad |
| | sensitizing-activating process | good |
| | catalyzing-accelerating process | good |

Referring to Table 1, after the activating process, a copper plating reaction was not generated regardless of the complexing agent. After the sensitizing-activating process and the catalyzing-accelerating process, the copper plating reaction was generated.

Then, the substrate is dipped in an electroless plating solution to form a copper plating film on a copper deposition region during an electroless plating process.

A metal ion receives electrons discharged when a reducing agent is oxidized, so that the metal may be reduced and transferred to a workpiece. Thus, in the electroless plating process, a reducing agent in a solution including copper ions reduces and deposits a metal on the workpiece.

The electroless plating solution includes a reducing agent and a copper ion provider. The reducing agent provides an electron or a plurality of electrons into a metal ion to reduce the metal ion to a metal. The reducing agent, for example, includes an aldehyde group material such as formaldehyde (HCHO).

The copper ion provider, for example, includes copper sulfate (CuSO₄.5H₂O) corresponding to a divalent ion. The copper sulfate is dissociated to provide the substrate with a copper ion.

The electroless plating solution may further include at least one of a complexing agent, a pH adjuster and a stabilizer. The complexing agent may be, for example, Rochelle salt or EDTA. The complexing agent prevents copper from being precipitated. The pH adjuster changes a concentration of sodium hydroxide (NaOH) to adjust the pH value of the electroless plating solution. The stabilizer prevents a reduction reaction at a remaining portion except for a plating portion, that is, the stabilizer prevents the plating solution from being naturally resolved. Thus, the stabilizer prevents a precipitate by aging of the plating solution from reacting with the reducing agent to generate hydrogen gas.

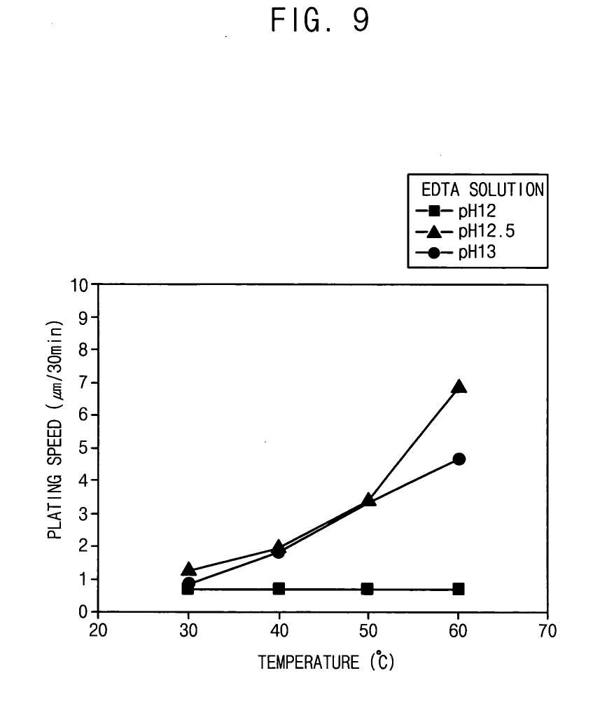

FIG. 9 is a graph which illustrates three curves which show plating speed as a function of temperature using a complexing agent of EDTA in a solution for three pH values. An electroless plating solution including copper sulfate (CuSO₄.5H₂O) of about 10 g/L as the copper ion provider, formaldehyde (HCHO) of about 10 ml/L as the reducing agent, EDTA of about 40 g/L serving as the complexing agent and sodium hydroxide (NaOH) as the pH adjuster were used as experimental conditions. Plating speeds were measured at temperatures of from about 30° C. to about 60° C., and measured in a pH range of from about pH12 to about pH13.

Referring to FIG. 9, it will be appreciated that plating speed was constant at a pH of about pH12, however the plating speed increased at above about pH12.5 as the temperature of the EDTA solution increased. Although the plating speed increased at a pH of about pH 13 as the temperature of the EDTA solution increased, a side reaction was generated. That is, the plating solution was greatly resolved. Thus, the results achieved with a solution pH of about pH12.5 were better.

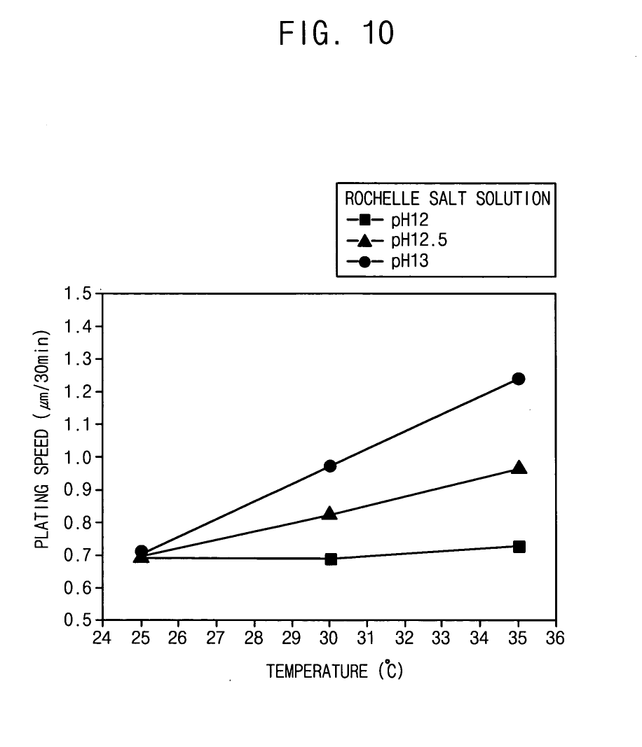

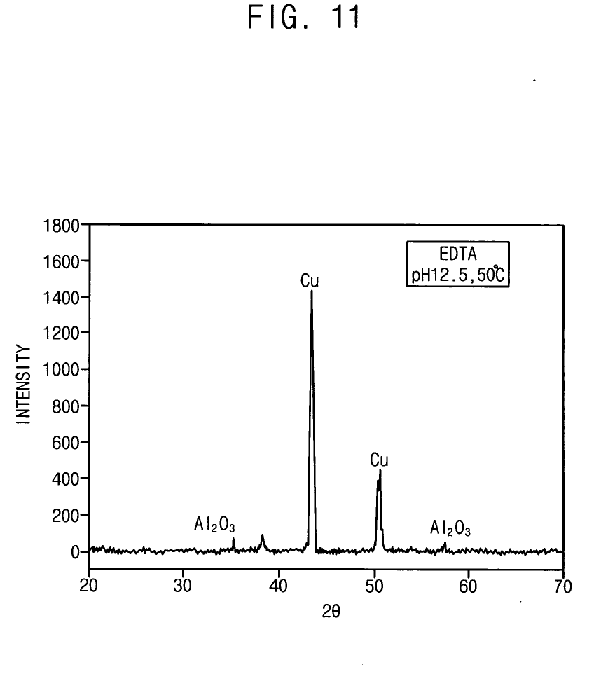

FIG. 10 is a graph which illustrates three curves which show plating speed as a function of temperature using a complexing agent of Rochelle salt in a solution for three values of a pH. An electroless plating solution including copper sulfate (CuSO₄.5H₂O) of about 10 g/L, formaldehyde (HCHO) of about 10 m/L, Rochelle salt of about 40 g/L and sodium hydroxide (NaOH) serving as the pH adjuster were used as experimental conditions. Plating speeds were measured in a temperature range of from about 25° C. to about 35° C., and measured in a range of about pH12 to about pH13.

Referring to FIG. 10, it will be appreciated that plating speed increased with an increase of temperature and a pH value of the Rochelle salt solution increased. However, the resulting plating thickness was below about 1 μm, which did not satisfy the requirement of having a plating thickness of from about 2 μm to about 3 μm. The Rochelle salt solution was very unstable, so that the Rochelle salt solution was resolved sensitively in accordance with the temperature and the pH of the Rochelle salt solution.

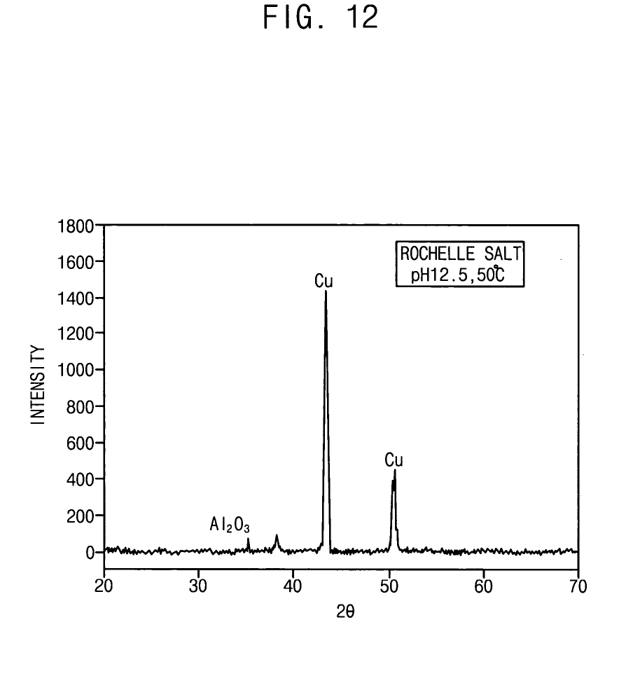

FIGS. 11 and 12 are graphs illustrating an X-ray diffraction pattern of a transparent substrate including a copper plating. In FIG. 11, the copper plating of the workpiece was generated at about pH12.5 and a temperature of about 50° C. using a complexing agent of EDTA. In FIG. 12, the copper plating of the workpiece was generated at about pH12.5 and a temperature of about 25° C. using a complexing agent of Rochelle salt.

Referring to FIGS. 11 and 12, the copper plating did not include compound or an impurity regardless of a kind of the complexing agent. Resistance characteristics of the copper plating were not related to the kind of the complexing agent.

Referring to FIG. 3B, a first barrier layer 413 and a second barrier layer 433 are deposited on the first metal layer 411 and the second metal layer 431, respectively, through a sputtering process. Thus, the first and second barrier layers 413 and 433 cover upper and lateral portions of the first and second metal layers 411 and 431, respectively.

The sputtering process is performed by controlling process conditions such as a partial pressure of oxygen gas, a process temperature, and heat-treatment, using a DC magnetron sputter.

The transparent substrate 401 is cleaned by ultrasonic cleaner using acetone, methanol and deionized water, successively, and then removed of moisture. Next, the transparent substrate 401 is fixed in a chamber having a pressure of about 6 Torr to about 10 Torr. Then, argon (Ar) gas and oxygen (O₂) gas are injected into the chamber to form the first and second barrier layers 413 and 433 including SnO₂ on the transparent substrate 401 using SnO₂—Sb₂O₃ (about five percents by weight) serving as a target material. Next, the transparent substrate 401 on which the first and second barrier layers 413 and 433 are formed is annealed.

Referring to FIG. 3C, silicon nitride is deposited on the transparent substrate 401 on which a gate electrode 414, a gate line (not shown) and a first electrode 434 of a storage capacitor 430 are formed to form a gate insulation layer 405.

Referring to FIG. 3D, amorphous silicon is deposited on the gate insulation layer 405. N+ type impurities are doped in the deposited amorphous silicon to form an active layer including an amorphous silicon layer 416a and an N+ amorphous silicon layer 416b disposed on the amorphous silicon layer 416a. Then, the active layer is partially etched to form a semiconductor layer pattern 416 including an amorphous silicon layer 416a and an N+ amorphous silicon layer 416b on the gate insulation layer 405 corresponding to the gate electrode 414.

A metal is deposited on gate insulation layer 405 on which the semiconductor layer pattern 416 is formed. The metal, for example, includes copper. A method of forming the metal including copper on the gate insulation layer 405 is substantially same as a method of forming the gate electrode 414 including copper. Thus, any further description therefor will be omitted.

Referring to FIG. 3D, an inorganic insulation material is coated on the gate insulation layer 405 on which the semiconductor layer pattern 416, a data line (not shown), a source electrode 418a and a drain electrode 418b are formed to form a passivation layer 420. The passivation layer 420 protects a thin film transistor (TFT) 410, and includes silicon nitride. An organic layer of material 425 is coated on the passivation layer 420.

Referring to FIG. 3E, organic layer 425 includes contact hole 450 formed to expose a portion of the drain electrode 418b through an etching process.

Then, an optically transparent and electrically conductive layer is formed on the organic layer 425 such that the optically transparent and electrically conducive layer is electrically connected to the drain electrode 418b through the contact hole 450. Next, the optically transparent and electrically conductive layer is patterned to form a pixel electrode 440.

Therefore, an array substrate including the first transparent substrate 401, the TFT 410, the storage capacitor 430, the data line, the gate line, the passivation layer 420, the organic layer 425 and the pixel electrode 440 is completely manufactured.

Referring to FIG. 3F, an opaque material is deposited on an upper substrate 201. The opaque material is partially removed to form a black matrix 210. After the opaque material and photoresist are coated on the upper substrate 201, the black matrix 210 may be formed in a photolithography process. The photolithography process includes an exposure process and a development process. The black matrix 210 may be formed on the transparent substrate 401.

A color filter 220 is formed on the second transparent substrate 201 on which the black matrix 210 is formed. An over-coating layer (not shown) may be formed on the upper substrate 201 on which the black matrix 210 and the color filter 220 are formed.

Then, a transparent conductive material is deposited on the upper substrate 201 on which the black matrix 210 and the color filter 220 are formed, to form a common electrode 230. A spacer (not shown) may be formed on the common electrode 230.

Therefore, a first substrate 200 including the upper substrate 201, the black matrix 210, the color filter 220 and the common electrode 230 is completely manufactured.

Liquid crystal is injected into between the first substrate 200 and a second substrate 400, and is sealed through a sealant (not shown) to form a liquid crystal layer 300. The liquid crystal may be dropped on the first substrate 200 or the second substrate 400 where the sealant is formed, and the first and second substrates 200 and 400 are combined with each other to form the liquid crystal layer 300.

According to the above, the gate electrode including copper, the gate line and the storage capacitor line is deposited through an electroless plating method, thereby increasing an adhesive force between a glass substrate and a metal layer including copper. In addition, a barrier layer prevents the diffusion of copper, so that a low resistance of the metal layer may be maintained.

According to the present invention, a metal wiring and a barrier layer on the metal wiring are formed, so that the diffusion of copper atoms may be prevented.

In addition, a metal layer is formed through an electroless plating method, so that an adhesive force between a glass substrate and a metal layer may be enhanced.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An electrically conductive structure comprising:
a layer of metal disposed on an insulating body; and
a barrier layer covering an upper face and a side face of the layer of metal, the barrier layer including a material having a melting point higher than a glass transition temperature of the insulating body.

2. The electrically conductive structure of claim 1, wherein the barrier layer comprises one of tin oxide (SnO₂) and zinc oxide (ZnO2).

3. The electrically conductive structure of claim 1, wherein the barrier layer comprises a conductive metal oxide.

4. The electrically conductive structure of claim 3, wherein the conductive metal oxide comprises tin oxide or zinc oxide.

5. The electrically conductive structure of claim 1, wherein the layer of metal comprises copper.

6. The electrically conductive structure of claim 1, wherein the layer of metal comprises a seed layer.

7. The electrically conductive structure of claim 6, wherein the seed layer comprises at least one selected from the group consisting of palladium (Pd), gold (Au), silver (Ag), tin (Sn), nickel (Ni), iron (Fe), platinum (Pt) and a mixture thereof.

8. A method of forming an electrically conductive structure, the method comprising:
forming a layer of metal on an insulating body; and
coating an upper face and a side face of the layer of metal with a barrier layer of material, the barrier layer of material having a melting point higher than a glass transition temperature of the insulating body to form a barrier layer preventing diffusion of atoms in the layer of metal.

9. The method of claim 8, wherein the layer of metal is formed by an electroless plating method.

10. The method of claim 9, wherein the electroless plating method comprises:
forming a seed on a metal deposition region of the insulating body where the layer of metal is to be formed; and
dipping the insulating body in an electroless plating solution comprising a reducing agent and a material for providing metal ions to grow the layer of metal on the metal deposition region.

11. The method of claim 10, wherein the seed comprises at least one selected from the group consisting of palladium (Pd), gold (Au), silver (Ag), tin (Sn), nickel (Ni), iron (Fe), platinum (Pt) and a mixture thereof.

12. The method of claim 10, wherein the seed is formed by:
adsorbing a tin ion on the metal deposition region; and
dipping the insulating body in an acid solution including metal chloride to deposit the seed on the metal deposition region using the tin ion serving as a medium.

13. The method of claim 12, wherein the tin ion is adsorbed by dipping the insulating body in a tin (II) chloride (SnCl₂) solution.

14. The method of claim 10, wherein the reducing agent comprises aldehyde.

15. The method of claim 10, wherein the electroless plating solution is alkaline.

16. The method of claim 15, wherein a pH of the electroless plating solution is in a range of about 12.5 to about 13.

17. The method of claim 10, wherein the electroless plating solution further comprises a complexing agent.

18. The method of claim 17, wherein the complexing agent comprises ethylene diamine tetra-acetic acid (EDTA).

19. The method of claim 10, prior to forming the seed, further comprising:
cleaning the insulating body; and
etching the cleaned insulating body.

20. The method of claim 19, wherein the insulating body is etched using an etching solution of sodium hydroxide of about 350 g/L to about 450 g/L.

21. The method of claim 8, wherein the barrier layer is formed by sputtering process.

22. An array substrate comprising:
an insulating body;
a switching element comprising:
a gate electrode electrically connected to gate lines and having a metal;
a first current electrode electrically connected to data lines;
a gate insulation layer insulating the gate electrode and the first current electrode from each other; and
a first barrier layer between the gate electrode and the gate insulation layer, the first barrier covering an upper face and a side face of the gate electrode, the first barrier layer including a material having a melting point higher than a glass transition temperature of the insulating body, the first barrier layer preventing diffusion of the metal; and
a pixel electrode electrically connected to a second current electrode of the switching element.

23. The array substrate of claim 22, wherein at least one of the first current electrode and the second current electrode comprises a substantially same material as that of the gate electrode.

24. The array substrate of claim 23, further comprising a passivation layer on the first and second current electrodes.

25. The array substrate of claim 24, further comprising a second barrier layer disposed between the first and second current electrodes and the passivation layer to prevent atoms of the metal from diffusing into the passivation layer.

26. The array substrate of claim 25, further comprising a storage capacitor electrically connected to the second current electrode, the storage capacitor having a first capacitor electrode including a metal.

27. The array substrate of claim 26, wherein the first barrier layer is disposed on the first capacitor electrode, the first barrier layer preventing diffusion of atoms in the metal.

28. A method of manufacturing an array substrate, comprising:
forming a gate electrode including a metal on an insulating body;
depositing a material having a melting point higher than a glass transition temperature of the insulating body on an upper face and a side face of the gate electrode to form a barrier layer preventing diffusion of atoms in the metal; and
successively forming a gate insulation layer, a first current electrode and a second current electrode on the insulating body including the barrier layer.

29. The method of claim 28, wherein the metal is formed by an electroless plating method.

30. The array substrate of claim 28, wherein the barrier layer includes one of tin oxide and zinc oxide.

31. A liquid crystal display panel comprising:
a first glass substrate including a common electrode;
a second glass substrate facing the first substrate, comprising:
a switching element having a gate electrode including a metal, a gate insulation layer, a first current electrode, a second current electrode, and a barrier layer between the gate electrode and the gate insulation layer, including a material having a melting point higher than a glass transition temperature of the first glass substrate, and preventing diffusion of the metal, and the switching element applying an image signal; and
a pixel electrode electrically connected to the switching element; and
a liquid crystal layer interposed between the first and second glass substrates.
